(19) United States
(12) Patent Application Publication
(10) Pub. No.: US 2025/0316514 A1
(43) Pub. Date: Oct. 9, 2025

(54) Substrate Conveyance Device

(71) Applicant: Hitachi High- Tech Corporation, Minato-ku, Tokyo (JP)

(72) Inventors: Keita KAWAKAMI, Tokyo (JP); Tomoki HANEISHI, Tokyo (JP)

(21) Appl. No.: 18/865,773

(22) PCT Filed: Jun. 1, 2022
(86) PCT No.: PCT/JP2022/022370

§ 371 Date: Nov. 14, 2024

(51) Int. Cl. H01L 21/677; B25J 11/00; H01L 21/687

(52) U.S. Cl. CPC H01L 21/67742; B25J 11/0095; H01L 21/68707

(57) ABSTRACT

Provided is a substrate conveyance device that can ensure safety of an operator without cutting off power supply of a conveyance robot. An operator-side shutter is provided between a storage container mounting portion and the outside of the device, and a conveyance robot-side shutter is provided between the conveyance robot and the storage container mounting portion.

### TECHNICAL FIELD

The present invention relates to a substrate conveyance device, and more particularly to a technology that is effective when applied to a substrate conveyance device that conveys, for example, semiconductor substrates.

### BACKGROUND ART

JP6822953B (PTL 1), JP2016-58481A (PTL 2), and JP5825948B (PTL 3) describe technologies that include a mechanism that blocks a conveyance robot from accessing a storage container mounting portion while an operator is accessing the storage container mounting portion.

### CITATION LIST

### Patent Literature

PTL 1: JP6822953B

PTL 2: JP2016-58481A

PTL 3: JP5825948B

### SUMMARY OF INVENTION

### Technical Problem

For example, in a substrate conveyance device that conveys substrates such as semiconductor wafers and reticles, an operation of placing a storage container storing the substrates on the storage container mounting portion is performed by the operator. On the other hand, the operations of taking out substrates from the storage container placed in the storage container mounting portion and conveying the substrates into a processing device that processes the substrates, or the operations of conveying the substrates out of the processing device and storing the substrates in the storage container are performed by a conveyance robot.

As such, the storage container mounting portion is a location accessed by both operators and the conveyance robot, but the conveyance robot is, for example, an industrial robot with a rated output of 80 W or more, and in order to ensure the safety of the operators, it is necessary to prevent contact between the operators and the conveyance robot at the storage container mounting portion. That is, in the substrate conveyance device, it is necessary to take measures to prevent contact between the operator and the conveyance robot.

In this regard, for example, when the operator performs the operation of placing the storage container on the storage container mounting portion, by cutting off a driving power supply of the conveyance robot, it is possible to prevent the conveyance robot from coming into contact with the operator.

However, when the driving power supply of the conveyance robot is cut off, it takes time to make the conveyance robot operable again. In addition, while the operator is performing the operation of placing the storage container on the storage container mounting portion, the conveyance robot cannot perform any work, which reduces the work efficiency of the substrate conveyance device.

Therefore, it is desirable to devise measures to prevent contact between the operator and the conveyance robot and ensure the safety of the operator without cutting off the driving power supply of the conveyance robot.

### Solution to Problem

In one embodiment, a substrate conveyance device includes: a conveyance robot that conveys a substrate; a first mounting portion in which a storage container for storing the substrate can be placed; a first shutter mechanism that is provided to be capable of blocking a first access path when the storage container or the first mounting portion is accessed from outside the device; a second shutter mechanism that is provided to be capable of blocking a second access path when the conveyance robot accesses the storage container; and a control unit that controls opening and closing operations of the first shutter mechanism and the second shutter mechanism.

### Advantageous Effects of Invention

According to one embodiment, it is possible to provide a substrate conveyance device capable of ensuring the safety of an operator without cutting off the power supply of a conveyance robot.

### BRIEF DESCRIPTION OF DRAWINGS

FIG. 1 is a perspective view schematically illustrating a semiconductor inspection device.

FIG. 2 is a top view schematically illustrating a configuration of a substrate conveyance device.

FIG. 3 is a side view schematically illustrating the configuration of the substrate conveyance device.

FIG. 4 is a diagram illustrating a state in which a shutter is closed.

FIG. 5 is a diagram illustrating a state in which the shutter is open.

FIG. 6 is a diagram illustrating a basic idea of an embodiment.

FIG. 7 is a flowchart illustrating the flow of operations of the substrate conveyance device when an operator accesses a storage container mounting portion.

FIG. 8 is a flowchart illustrating the flow of operations of the substrate conveyance device when a conveyance robot accesses the storage container mounting portion.

FIG. 9 is a flowchart illustrating the operation of the substrate conveyance device following FIG. 8, and illustrating an operation of transitioning to a state in which an operator can access the storage container mounting portion after the conveyance robot has accessed the storage container mounting portion.

FIG. 10 is a diagram schematically illustrating a configuration of the substrate conveyance device according to an embodied mode.

FIG. 11 is a diagram illustrating features of the embodied mode.

FIG. 12 is a diagram illustrating a storage container called an “open cassette”.

FIG. 13 is a diagram illustrating a configuration example of a shutter mechanism.

FIG. 14 is a diagram illustrating a locking mechanism in Modification Example 1.

FIG. 15 is a diagram illustrating an example in which a light curtain is provided to detect that an operator is accessing a storage container mounting portion, and illustrating an example in which a light curtain is provided to detect a conveyance robot is accessing a storage container mounting portion.

FIG. 16 is a diagram illustrating substrate conveyance devices according to Modification Examples 4 and 5.

### DESCRIPTION OF EMBODIMENTS

In all the drawings for describing the embodiments, the same members are generally given the same reference numerals, and repeated descriptions thereof will be omitted. In order to make the drawings easier to understand, hatching may be used even in plan views.

### EMBODIMENT

First, an overview of a substrate conveyance device will be described. In particular, in the present embodiment, a semiconductor inspection device including a substrate conveyance device will be described as an example of the substrate conveyance device. However, the substrate conveyance device in the present embodiment is not limited to this example, and can be widely applied to substrate conveyance devices associated with substrate processing devices that process substrates. Further, examples of the substrate conveyed by the substrate conveyance device include semiconductor wafers (semiconductor substrates) and reticles, but in the present embodiment, the substrate will be described by taking a semiconductor substrate as an example.

### Overview of Substrate Inspection Device

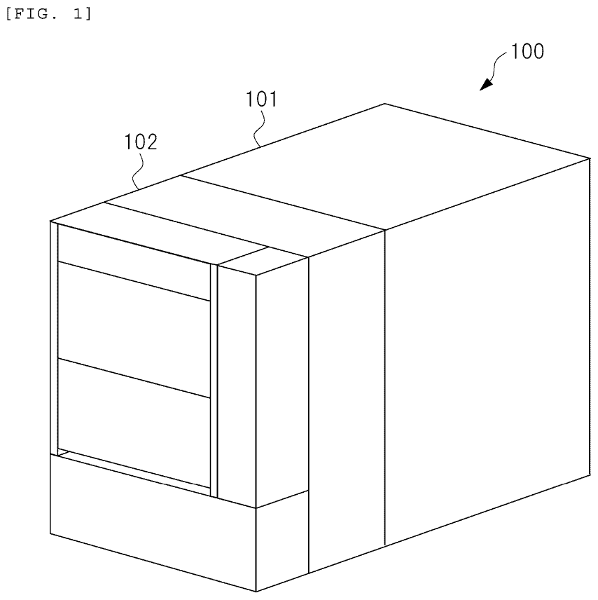

FIG. 1 is a perspective view schematically showing a semiconductor inspection device 100.

In FIG. 1, the semiconductor inspection device 100 includes a semiconductor substrate processing unit 101 provided at the rear of the device, and also includes a substrate conveyance device 102 provided at the front of the device.

The semiconductor substrate processing unit 101 includes a main function as the semiconductor inspection device 100 for inspecting or measuring a semiconductor substrate, and a control unit including a computer system for controlling the function and a power supply. For example, when the semiconductor inspection device 100 is a critical dimension scanning electron microscope (SEM), the semiconductor substrate processing unit 101 has an electron gun section, a stage section, a vacuum exhaust section, and a power supply section. On the other hand, the control unit is configured to control the operations of these components, and is configured to perform dimensional measurement of a fine pattern formed on a semiconductor substrate by controlling these components.

### Configuration of Substrate Conveyance Device

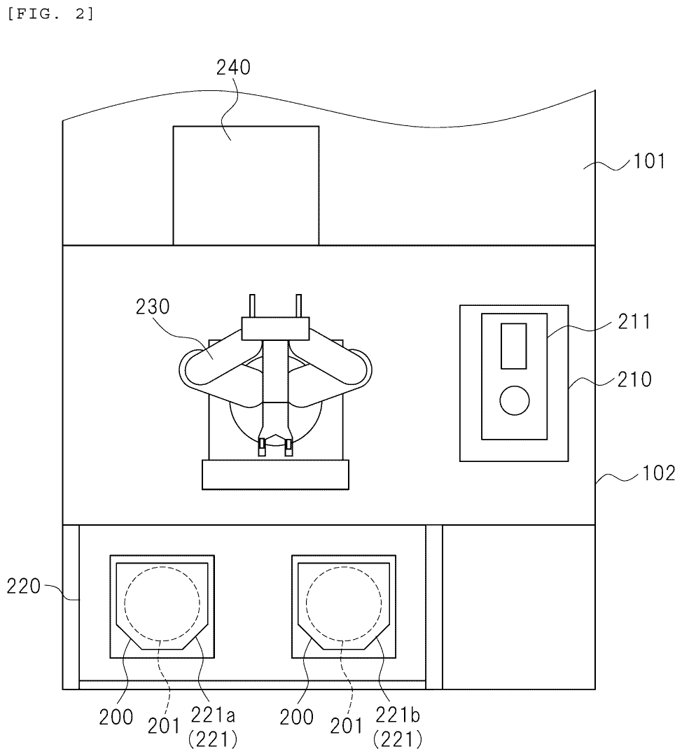

FIG. 2 is a top view schematically showing a configuration of the substrate conveyance device 102.

In FIG. 2, the substrate conveyance device 102 includes a control unit 210, a pre-aligner 211, a storage container mounting portion 220, and a conveyance robot 230.

The control unit 210 is configured to control the operation to convey the semiconductor substrate 201 by the conveyance robot 230.

The pre-aligner 211 is a unit configured to measure the amount of eccentricity of the semiconductor substrate 201 and correct the amount of eccentricity, and to detect an orientation flat and a notch of the semiconductor substrate 201 and align the orientation flat and the notch.

The storage container mounting portion 220 is configured to place a storage container 200 thereon, and includes a storage container stand 221 on which the storage container 200 is placed. The substrate conveyance device 102 is provided with at least one storage container stand 221, and for example, as shown in FIG. 2, a storage container stand 221a and a storage container stand 221b are provided. The storage containers 200 can be placed on the storage container stand 221a and the storage container stand 221b simultaneously.

Although not shown in the figure, the storage container mounting portion 220 is provided with sensors, switches and readers for checking whether the storage container 200 is properly placed on the storage container stand 221, storing the placement history of the storage container 200, and checking whether the semiconductor substrate 201 has protruded from the storage container 200 placed on the storage container stand 221.

The conveyance robot 230 is configured to be capable of conveying the semiconductor substrate 201, and is configured to operate under the control of the control unit 210.

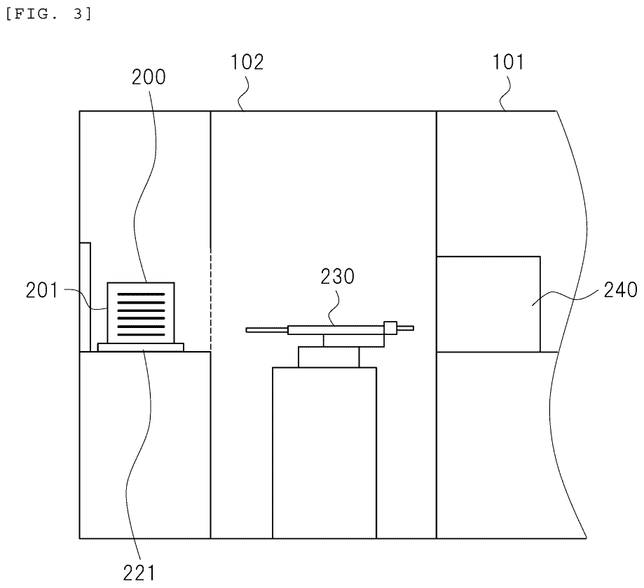

FIG. 3 is a side view schematically showing a configuration of the substrate conveyance device 102.

As shown in FIG. 3, it can be seen that in the substrate conveyance device 102, the storage container 200 is placed on the storage container stand 221 and a plurality of semiconductor substrates 201 are stored inside the storage container 200. The conveyance robot 230 is disposed in a space between an upper port 240 provided in the semiconductor substrate processing unit 101 and the storage container 200 placed on the storage container stand 221 of the substrate conveyance device 102.

### Operation of Substrate Conveyance Device

Subsequently, the operation of the substrate conveyance device 102 will be described with reference to FIG. 2.

First, an operator manually places the storage container 200 storing the plurality of semiconductor substrates 201 on the storage container stand 221 of the storage container mounting portion 220. Thereafter, under the control of the control unit 210, the conveyance robot 230 takes out the semiconductor substrate 201 from the storage container 200 placed on the storage container stand 221, and then places the taken semiconductor substrate 201 on the pre-aligner 211. Next, in the pre-aligner 211, the amount of eccentricity of the semiconductor substrate 201 is corrected, and the orientation flat and the notch are aligned.

Thereafter, under the control of the control unit 210, the conveyance robot 230 takes out the semiconductor substrate 201 from the pre-aligner 211 and conveys the semiconductor substrate 201 to the upper port 240 for delivery to the semiconductor substrate processing unit 101.

The semiconductor substrate 201 placed in the upper port 240 is processed in the semiconductor substrate processing unit 101. Subsequently, the semiconductor substrate 201 processed in the semiconductor substrate processing unit 101 is placed back in the upper port 240. Thereafter, under the control of the control unit 210, the conveyance robot 230 picks up the semiconductor substrate 201 placed in the upper port 240, and then stores the semiconductor substrate 201 in the storage container 200 placed on the storage container stand 221 of the storage container mounting portion 220. Then, the operator manually conveys the storage container 200 storing the processed semiconductor substrates 201 to the outside of the substrate conveyance device 102.

The substrate conveyance device 102 operates as described above.

### Consideration of Improvements

For example, the conveyance robot 230 is an industrial robot with a rated output of 80 W or more, and requires that a physical barrier be provided to protect the operator from coming into contact with the conveyance robot 230, according to “SEMI” standards.

In this regard, the conveyance robot 230 accesses the storage container mounting portion 220. On the other hand, the storage container mounting portion 220 is also a place that the operator can access in order to place the storage container 200 on the storage container stand 221 of the storage container mounting portion 220. Therefore, unless any measures are taken, there will be no physical barrier between the operator and the conveyance robot 230 at the storage container mounting portion 220. Therefore, since there is no physical barrier between the operator and the conveyance robot 230, for example, when the operator is accessing the storage container mounting portion 220 and the conveyance robot 230 accesses the storage container mounting portion 220, there is a risk of contact between the operator and the conveyance robot 230. For this reason, for example, a technique of providing a shutter mechanism (sometimes called a shutter) at the boundary between the operator and the storage container mounting portion 220 may be considered.

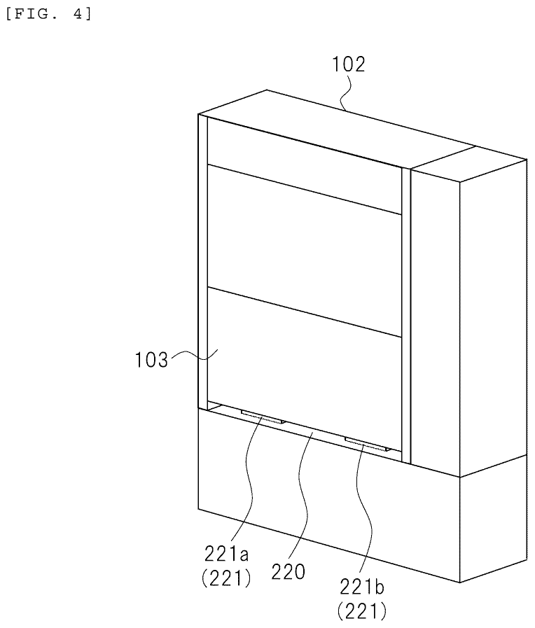

FIG. 4 is a diagram showing a state in which a shutter 103 is closed. As shown in FIG. 4, the operator (outside the device) and the storage container mounting portion 220 are blocked by the shutter 103. Therefore, operators are unable to access the storage container mounting portion 220, but the conveyance robot 230 is protected by a physical barrier (shutter 103) and is therefore able to access the storage container mounting portion 220.

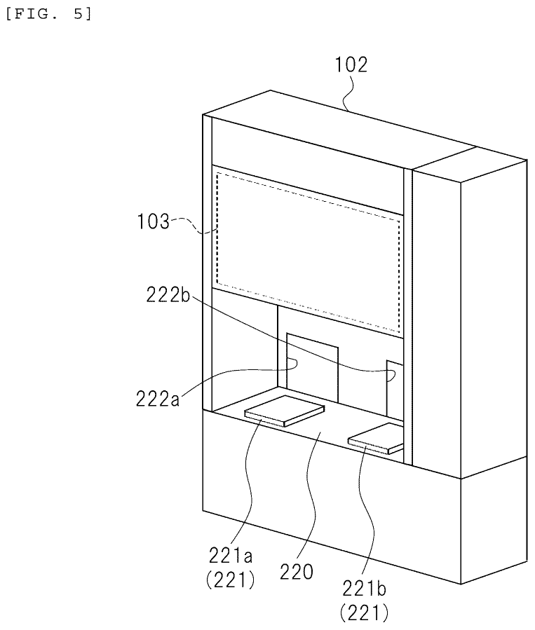

FIG. 5 is a diagram showing a state in which the shutter 103 is open. As shown in FIG. 5, conveyance openings 222a and 222b through which the conveyance robot 230 takes out the semiconductor substrate 201 from the storage container 200 and stores the semiconductor substrate 201 in the storage container 200 are provided between the storage container mounting portion 220 and the conveyance robot 230. Therefore, it can be seen that even when the shutter 103 is closed as shown in FIG. 4, the conveyance robot 230 can access the storage container mounting portion 220 via the conveyance opening 222a or the conveyance opening 222b.

In FIG. 5, when the shutter 103 is open, there is no physical barrier (shutter 103) between the operator and the conveyance robot 230. For this reason, there is a risk of contact between the operator and the conveyance robot 230. However, for example, an interlock circuit linked to the opening of the shutter 103 cuts off the driving power supply of the conveyance robot 230. As a result, since the conveyance robot 230 cannot operate, the operator can safely access the storage container mounting portion 220.

In this regard, when the driving power supply of the conveyance robot 230 is cut off, it takes time to make the conveyance robot 230 operable again. In addition, while the operator is performing the operation of placing the storage container 200 on the storage container mounting portion 220, the conveyance robot 230 cannot perform any work, which reduces the work efficiency of the substrate conveyance device 102. That is, in terms of technology of providing the shutter 103 as a physical barrier and cutting off the driving power supply of the conveyance robot 230, there is room for improvement from the viewpoint of ensuring the safety of operators while suppressing a decrease in the work efficiency of the substrate conveyance device 102.

Therefore, in the present embodiment, some measures are taken to overcome the above-described room for improvement. The technical concept of the present embodiment based on these measures will be described below.

### Basic Idea of Embodiment

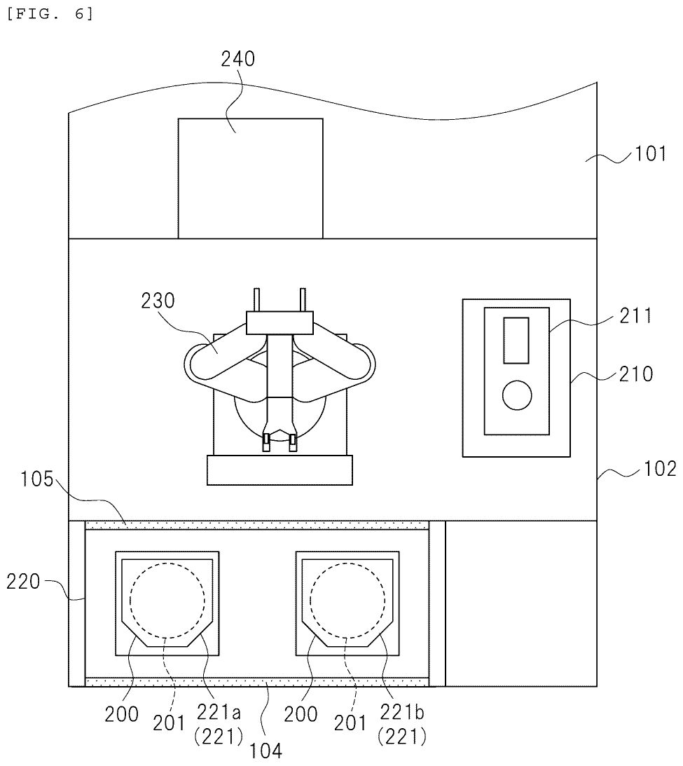

FIG. 6 is a diagram illustrating a basic idea of the present embodiment.

In FIG. 6, the basic idea is to provide an operator-side shutter 104 (first shutter mechanism) between the outside of the device and the storage container mounting portion 220, and provide a conveyance robot-side shutter 105 (second shutter mechanism) between the conveyance robot 230 and the storage container mounting portion 220. Specifically, the basic idea is that the substrate conveyance device 102 is provided with the operator-side shutter 104 disposed so as to be capable of blocking a first access path when accessing the storage container mounting portion 220 from outside the device, and the conveyance robot-side shutter 105 disposed so as to be capable of blocking a second access path when the conveyance robot 230 accesses the storage container mounting portion 220. In other words, the basic idea is that the substrate conveyance device 102 is provided with a double shutter mechanism consisting of the operator-side shutter 104 and the conveyance robot-side shutter 105.

According to this basic idea, for example, when an operator accesses the storage container mounting portion 220, the operator-side shutter 104 is opened and the conveyance robot-side shutter 105 is closed. As a result, because the conveyance robot-side shutter 105 is in a closed state, the conveyance robot 230 cannot access the storage container mounting portion 220. On the other hand, since the operator-side shutter 104 is in the open state, the operator can access the storage container mounting portion 220.

In other words, according to the basic idea, when the operator accesses the storage container mounting portion 220, there is always a physical barrier called the conveyance robot-side shutter 105 between the operator and the conveyance robot 230, so the operator can safely access the storage container mounting portion 220 without worrying about contact with the conveyance robot 230.

Thus, according to the basic idea, when the operator accesses the storage container mounting portion 220, the conveyance robot 230 is prevented from accessing the storage container mounting portion 220 by the conveyance robot-side shutter 105. Therefore, according to the basic idea, when the operator accesses the storage container mounting portion 220, it is no longer necessary to cut off the driving power supply of the conveyance robot 230 in order to prevent contact between the conveyance robot 230 and the operator. Therefore, according to the basic idea, it is not necessary to turn on the driving power supply of the conveyance robot 230 that has been cut off, and as a result, it is possible to save time in making the conveyance robot 230 operable. Therefore, according to this basic idea, a significant effect can be obtained in that the safety of the operators can be ensured while suppressing a decrease in the work efficiency of the substrate conveyance device 102.

On the other hand, according to the basic idea, for example, when the conveyance robot 230 accesses the storage container mounting portion 220, the operator-side shutter 104 is closed and the conveyance robot-side shutter 105 is opened. Thus, the operator cannot access the storage container mounting portion 220 because the operator-side shutter 104 is in the closed state. On the other hand, since the conveyance robot-side shutter 1045 is in an open state, the conveyance robot 230 can access the storage container mounting portion 220 while reliably preventing contact with the operator.

In the basic idea in which the substrate conveyance device 102 is provided with the double shutter mechanism consisting of the operator-side shutter 104 and the conveyance robot-side shutter 105, the operation of the substrate conveyance device 102 to reliably prevent contact between the operator and the conveyance robot 230 will be described below.

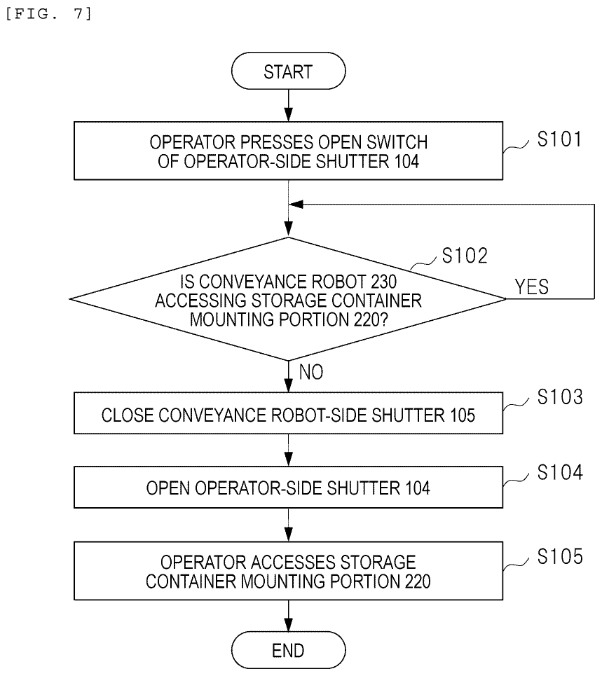

FIG. 7 is a flowchart illustrating the flow of operations of the substrate conveyance device 102 when an operator accesses the storage container mounting portion 220.

In FIG. 7, it is first assumed that the operator-side shutter 104 is in a closed state. It is also assumed that the substrate conveyance device 102 is provided with an open switch that serves as a trigger for opening the operator-side shutter 104.

When the operator accesses the storage container mounting portion 220, the operator presses the open switch that serves as a trigger for opening the operator-side shutter 104 (S101). Then, the control unit 210 of the substrate conveyance device 102 determines whether the conveyance robot 230 is accessing the storage container mounting portion 220 (S102). When the control unit 210 determines that the conveyance robot 230 is accessing the storage container mounting portion 220, the control unit 210 waits until the conveyance robot 230 ends access to the storage container mounting portion 220. On the other hand, when the control unit 210 determines that the conveyance robot 230 is not accessing the storage container mounting portion 220, the control unit 210 closes the conveyance robot-side shutter 105 (S103).

Subsequently, the control unit 210 opens the operator- side shutter 104 (S104). Thus, since the conveyance robot-side shutter 105 is in a closed state, access by the conveyance robot 230 to the storage container mounting portion 220 is blocked, while the operator can safely access the storage container mounting portion 220 (S105).

In this way, the control unit 210 is configured to perform control to make a transition from a phase in which the operator-side shutter 104 is in a closed state to a first phase in which the operator-side shutter 104 is in an open state and the conveyance robot-side shutter 105 is in a closed state, thereby enabling the operator to access the storage container mounting portion 220.

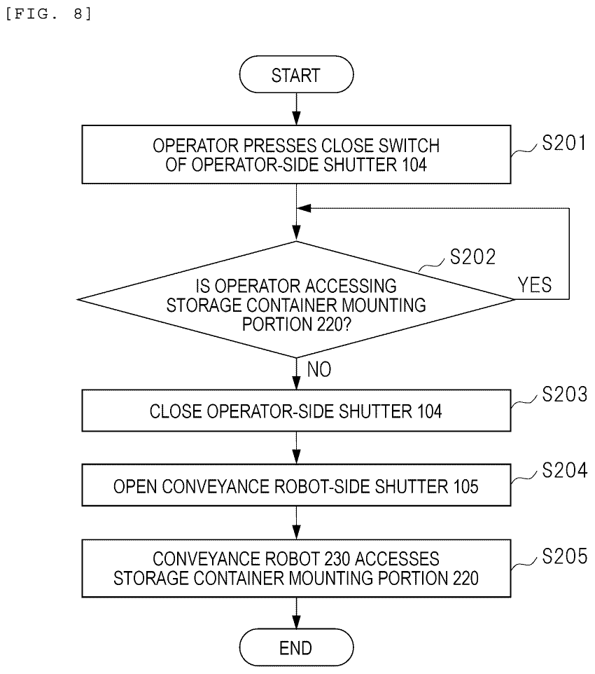

FIG. 8 is a flowchart illustrating the flow of operations of the substrate conveyance device 102 when the conveyance robot 230 accesses the storage container mounting portion 220.

In FIG. 8, it is first assumed that the operator-side shutter 104 is in an open state. It is also assumed that the substrate conveyance device 102 is provided with a close switch that serves as a trigger for closing the operator-side shutter 104.

When the operator ends the operation at the storage container mounting portion 220, the operator presses the close switch which serves as a trigger for closing the operator-side shutter 104 (S201). Then, the control unit 210 of the substrate conveyance device 102 determines whether the operator is accessing the storage container mounting portion 220 (S202). When the control unit 210 determines that the operator is accessing the storage container mounting portion 220, the control unit 210 waits until the operator ends access to the storage container mounting portion 220. On the other hand, when the control unit 210 determines that the operator is not accessing the storage container mounting portion 220, the control unit 210 closes the operator-side shutter 104 (S203).

Subsequently, the control unit 210 opens the conveyance robot-side shutter 105 (S204). Thus, since the operator-side shutter 104 is in a closed state, access by the operator to the storage container mounting portion 220 is blocked, while the conveyance robot 230 can access the storage container mounting portion 220 (S205).

In this way, the control unit 210 is configured to perform control to make a transition from the first phase in which the operator-side shutter 104 is in an open state and the conveyance robot-side shutter 105 is in a closed state to a second phase in which the operator-side shutter 104 is closed, and then the conveyance robot-side shutter 105 is opened, thereby enabling the conveyance robot 230 to take out the substrate from the storage container.

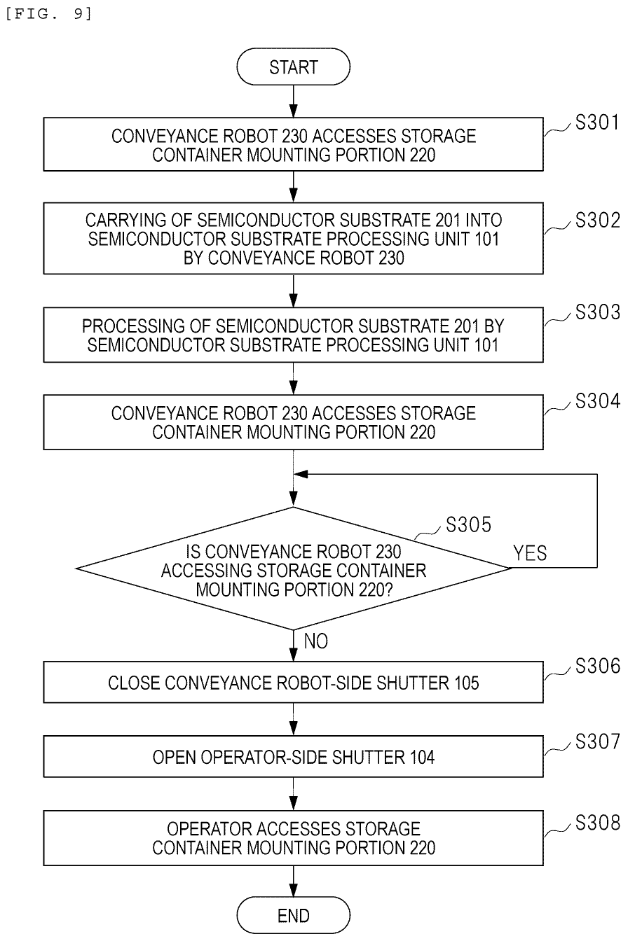

FIG. 9 is a flowchart illustrating the operation of the substrate conveyance device 102 following FIG. 8, and illustrating an operation of transitioning to a state in which the operator can access the storage container mounting portion 220 after the conveyance robot 230 has accessed the storage container mounting portion 220.

In the second phase in which the operator-side shutter 104 is in a closed state and the conveyance robot-side shutter 105 is in an open state, the conveyance robot 230 accesses the storage container mounting portion 220 and takes out the semiconductor substrate 201 from the storage container 200 (S301). Then, under the control of the control unit 210, the conveyance robot 230 conveys the semiconductor substrate 201 taken out from the storage container 200 into the semiconductor substrate processing unit 101 (S302). Next, after the semiconductor substrate 201 has been processed in the semiconductor substrate processing unit 101 (S303), the conveyance robot 230, under the control of the control unit 210, takes out the semiconductor substrate 201 processed in the semiconductor substrate processing unit 101 from the semiconductor substrate processing unit 101. Then, under the control of the control unit 210, the conveyance robot 230 accesses the storage container mounting portion 220 and stores the semiconductor substrate 201 in the storage container 200 (S304).

Subsequently, the control unit 210 determines whether the conveyance robot 230 is accessing the storage container mounting portion 220 (S305). When the control unit 210 determines that the conveyance robot 230 is accessing the storage container mounting portion 220, the control unit 210 waits until the conveyance robot 230 ends access to the storage container mounting portion 220. On the other hand, when the control unit 210 determines that the conveyance robot 230 is not accessing the storage container mounting portion 220, the control unit 210 closes the conveyance robot-side shutter 105 (S306).

Then, the control unit 210 opens the operator-side shutter 104 (S307). Thus, since the conveyance robot-side shutter 105 is in a closed state, access by the conveyance robot 230 to the storage container mounting portion 220 is blocked, while the operator can safely access the storage container mounting portion 220 (S308).

In this way, when the semiconductor substrate 201 is conveyed into the storage container 200 by the conveyance robot 230 in the second phase, the control unit 210 is configured to make a transition from the second phase to a third phase in which the conveyance robot-side shutter 105 is closed and then the operator-side shutter 104 is opened.

That is, as shown in FIG. 9, the operation of opening the operator-side shutter 104 can be performed automatically under the control of the control unit 210 without the operator pressing the open switch, after all processes in the semiconductor substrate processing unit 101 for the semiconductor substrate 201 stored in the storage container 200 specified by the operator has been completed and the semiconductor substrate 201 has been stored back in the storage container 200 by the conveyance robot 230.

This eliminates the need for the operator to press the open switch after processes (inspection, measurement, or the like) of the semiconductor substrate 201 are completed, thereby improving usability of the substrate conveyance device 102 for the operator.

According to the basic idea described above, by providing the substrate conveyance device 102 with the double shutter mechanism consisting of the operator-side shutter 104 and the conveyance robot-side shutter 105, it is no longer necessary to cut off the driving power supply of the conveyance robot 230 in order to prevent contact between the conveyance robot 230 and the operator. As a result, according to this basic idea, it is possible to ensure the safety of the operators while suppressing a decrease in the work efficiency of the substrate conveyance device 102.

### Consideration of Further Improvements

The basic idea is a technical idea useful in that the safety of the operator can be reliably ensured without cutting off the driving power supply of the conveyance robot 230. In this regard, the inventor has further studied this basic idea and found that there is room for improvement in terms of improving the work efficiency of the substrate conveyance device 102. Therefore, this room for improvement will be described.

In FIG. 6, the substrate conveyance device 102 is provided with the operator-side shutter 104 and the conveyance robot-side shutter 105. For example, when the operator accesses the storage container mounting portion 220, the control unit 210 controls the operator-side shutter 104 to be in an open state and the conveyance robot-side shutter 105 to be in a closed state. This allows the operator to access the storage container mounting portion 220 while blocking access to the storage container mounting portion 220 by the conveyance robot 230. This means that, according to the basic idea, contact between the operator and the conveyance robot 230 is prevented, ensuring the safety of the operator, but it also means that when the operator is accessing the storage container mounting portion 220, the conveyance robot 230 cannot access the storage container mounting portion 220 to perform work.

For example, in FIG. 6, the storage container mounting portion 220 of the substrate conveyance device 102 includes the storage container stand 221a and the storage container stand 221b. Therefore, for example, when the operator-side shutter 104 is in an open state and the operator accesses the storage container stand 221a, the operator does not access the storage container stand 221b.

Here, when the conveyance robot 230 can access the storage container stand 221b that is not being accessed by the operator, the conveyance robot 230 can work on the storage container stand 221b while the operator works on the storage container stand 221a, which is considered to improve the work efficiency of the substrate conveyance device 102.

However, according to the basic idea, when the operator-side shutter 104 is in an open state, the conveyance robot-side shutter 105 is in a closed state. Therefore, according to the basic idea, the conveyance robot 230 cannot access the storage container stand 221b that is not accessed by the operator. In other words, in the basic idea, there is room for improvement from the viewpoint of improving the work efficiency of the substrate conveyance device 102.

Therefore, in an embodied mode, some measures are taken for the room for improvement present in the basic idea. The following describes the embodied mode based on these measures.

### Embodied Mode

### <<Configuration of Substrate Conveyance Device>>

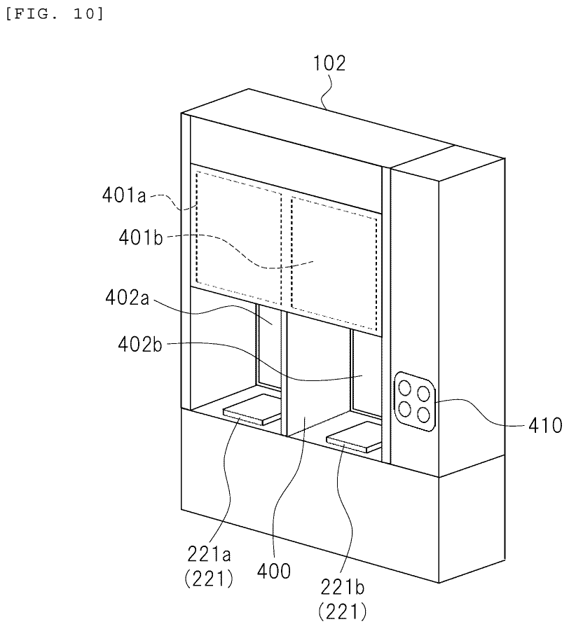

FIG. 10 is a diagram schematically showing a configuration of the substrate conveyance device 102 according to the embodied mode.

As shown in FIG. 10, the substrate conveyance device 102 includes the storage container stand 221a and the storage container stand 221b, and between the storage container stand 221a and the storage container stand 221b, a partition wall 400 is provided to separate the storage container stand 221a and the storage container stand 221b.

Then, an operator-side shutter 401a is provided between the storage container stand 221a separated by the partition wall 400 and the outside of the device. On the other hand, an operator-side shutter 401b is provided between the storage container stand 221b separated by the partition wall 400 and the outside of the device.

In addition, a conveyance robot-side shutter 402a is provided between the storage container stand 221a and the conveyance robot 230 (not shown in FIG. 10). On the other hand, a conveyance robot-side shutter 402b is provided between the storage container stand 221b and the conveyance robot 230.

The operator-side shutter 401a, the operator-side shutter 401b, the conveyance robot-side shutter 402a, and the conveyance robot-side shutter 402b each are configured to perform opening and closing operations under the control of the control unit 210 (not shown in FIG. 10). In particular, the substrate conveyance device 102 is provided with a switch 410, and is configured so that the switch 410 serves as a trigger to perform the opening and closing operations of the operator-side shutters 401a and 401b. On the other hand, the conveyance robot-side shutter 402a and the conveyance robot-side shutter 402b are provided with a function of recognizing an open state and a closed state, and opening and closing operations are performed under the control of the control unit 210 based on this function.

Thus, the substrate conveyance device 102 in the embodied mode includes a first mounting portion (storage container stand 221a) and a second mounting portion (storage container stand 221b) on which the storage container 200 (not shown in FIG. 10) can be placed. Here, the first mounting portion and the second mounting portion are separated by the partition wall 400. The substrate conveyance device 102 has the operator-side shutter 401a disposed so as to be capable of blocking a first access path when the storage container 200 or the first mounting portion is accessed from outside the device, the conveyance robot-side shutter 402a disposed so as to be capable of blocking a second access path when the conveyance robot 230 accesses the storage container 200, the operator-side shutter 401b disposed so as to be capable of blocking a third access path when the storage container 200 or the second mounting portion is accessed from outside the device, and the conveyance robot-side shutter 402b disposed so as to be capable of blocking a fourth access path when the conveyance robot 230 accesses the storage container 200. Furthermore, the substrate conveyance device 102 includes a control unit configured to control the opening and closing operations of each of the operator-side shutter 401a, the operator-side shutter 401b, the conveyance robot-side shutter 402a, and the conveyance robot-side shutter 402b.

The substrate conveyance device 102 in the embodied mode is configured as described above.

<<Operation of substrate conveyance device>>

Next, the operation of the substrate conveyance device 102 will be described with reference to FIG. 10.

For example, a case is considered where an operator accesses the storage container stand 221a. In this case, first, the operator presses an open switch included in the switch 410 to open the operator-side shutter 401a. Thus, pressing the open switch serves as a trigger for the control unit 210 to open the operator-side shutter 401a. In this case, the control unit 210 closes the conveyance robot-side shutter 402a that faces the operator-side shutter 401a. Furthermore, the control unit 210 closes the operator-side shutter 401b and opens the conveyance robot-side shutter 402b that faces the operator-side shutter 401b. In this way, when the operator-side shutter 401a is in the open state and the conveyance robot-side shutter 402a is in the closed state, the operator-side shutter 401b is set to the closed state and the conveyance robot-side shutter 402b is set to the open state. This allows the operator to access the storage container stand 221a, and allows the conveyance robot 230 to access the storage container stand 221b.

Subsequently, a case is considered where the operator accesses the storage container stand 221b. In this case, first, the operator presses an open switch included in the switch 410 to open the operator-side shutter 401b. Thus, pressing the open switch serves as a trigger for the control unit 210 to open the operator-side shutter 401b. In this case, the control unit 210 closes the conveyance robot-side shutter 402b that faces the operator-side shutter 401b. Furthermore, the control unit 210 closes the operator-side shutter 401a and opens the conveyance robot-side shutter 402a that faces the operator-side shutter 401a. In this way, when the operator-side shutter 401b is in the open state and the conveyance robot-side shutter 402b is in the closed state, the operator-side shutter 401a is set to the closed state and the conveyance robot-side shutter 402a is set to the open state. This allows the operator to access the storage container stand 221b, and allows the conveyance robot 230 to access the storage container stand 221a.

### <<Features of Embodied Mode>>

Subsequently, features of the specific embodiment will be described.

The features of the specific embodiment are that, for example, as shown in FIG. 10, the partition wall 400 is provided between the storage container stand 221a and the storage container stand 221b, and a shutter provided on the storage container stand 221a side and a shutter provided on the storage container stand 221b side are separately provided. In other words, the features are that the operator-side shutter 401a is provided between the storage container stand 221a on the left side of the partition wall 400 and the outside of the device, and the conveyance robot-side shutter 402a is provided between the storage container stand 221a and the conveyance robot 230, while the operator-side shutter 401b is provided between the storage container stand 221b on the right side of the partition wall 400 and the outside of the device, and the conveyance robot-side shutter 402b is provided between the storage container stand 221b and the conveyance robot 230. Based on this configuration, when the operator-side shutter 401a is in the open state and the conveyance robot-side shutter 402a is in the closed state, the control unit 210 controls the operator-side shutter 401b to be in the closed state and the conveyance robot-side shutter 402b to be in the open state, whereas when the operator-side shutter 401a is in the closed state and the conveyance robot-side shutter 402a is in the open state, the control unit 210 controls the operator-side shutter 401b to be in the open state and the conveyance robot-side shutter 402b to be in the closed state.

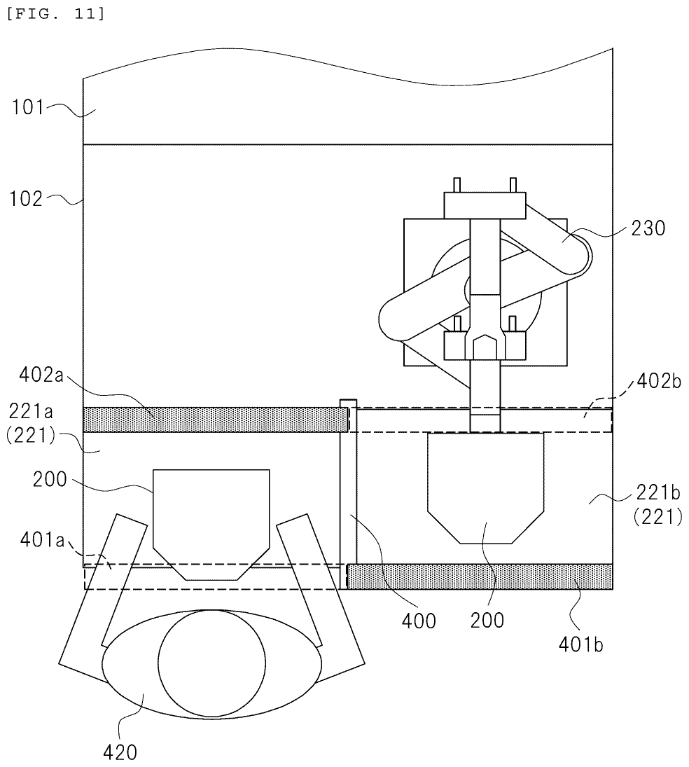

As a result, for example, as shown in FIG. 11, in the storage container stand 221a, when the operator-side shutter 401a is in an open state, and the conveyance robot-side shutter 402a is in a closed state, an operator 420 can access the storage container 200 placed on the storage container stand 221a. In this case, the control unit 210 performs controls such that in the storage container stand 221b, the operator-side shutter 401b is in a closed state and the conveyance robot-side shutter 402b is in an open state. As a result, as shown in FIG. 11, the conveyance robot 230 can access the storage container 200 placed on the storage container stand 221b. Thus, according to the features of the specific embodiment, access of the operator 420 to the storage container stand 221a and access of the conveyance robot 230 to the storage container stand 221b can be performed simultaneously. Therefore, according to this feature, the work efficiency of the substrate conveyance device 102 can be improved. According to the features, the partition wall 400 is provided between the storage container stand 221a and the storage container stand 221b. Therefore, even when the operator 420 accesses the storage container stand 221a and the conveyance robot 230 accesses the storage container stand 221b simultaneously, the partition wall 400 can prevent contact between the operator 420 and the conveyance robot 230. From the above, according to the features of the specific embodiment, a significant effect can be obtained in that the work efficiency of the substrate conveyance device 102 can be improved while reliably ensuring the safety of the operator 420.

### <<Application to Open Cassette>>

The above-described technical idea is particularly effective when applied to the case where an “open cassette” is used as the storage container. For example, there is a configuration in which a storage container is placed in an enclosed space (for example, a chamber) and a conveyance robot accesses the storage container within the enclosed space. In this configuration, since the conveyance robot accesses the storage container within the enclosed space, the enclosed space, which acts as a physical barrier, is necessarily present between the operator and the storage container. Therefore, it is considered that the safety of the operator is unlikely to be threatened due to contact between the operator and the conveyance robot.

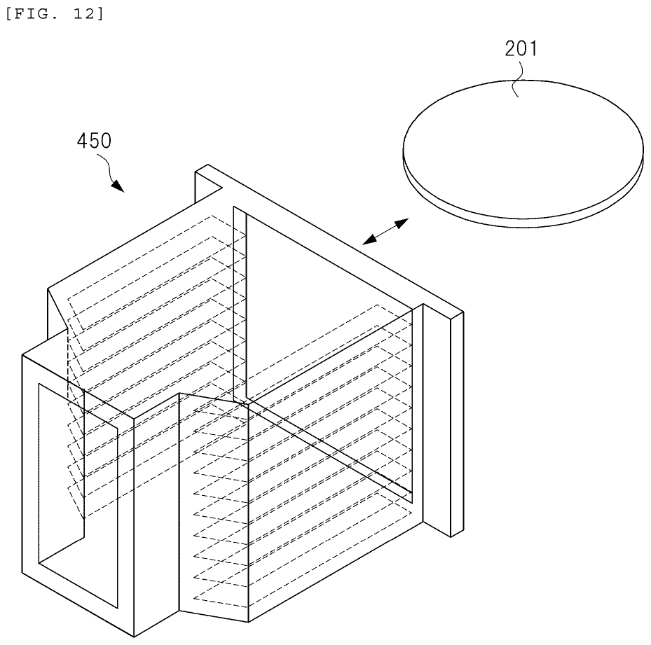

For this, for example, FIG. 12 is a diagram illustrating a storage container called an “open cassette 450”. Such the “open cassette 450” is not placed in the enclosed space and accessed by the conveyance robot, but is placed on the storage container stand 221 of the substrate conveyance device 102 and accessed by the conveyance robot. Moreover, this “open cassette 450” is manually placed on the storage container stand 221 by an operator. Therefore, when the “open cassette 450” is used as a storage container, both the operator and the conveyance robot can access the “open cassette 450” on the storage container stand 221 without any physical barrier. This means that when the “open cassette 450” is used as a storage container, contact between the operator and the conveyance robot is likely to occur, making it important to ensure the safety of the operator. Therefore, when the “open cassette 450” is used as a storage container, the safety of the operators can be reliably ensured by employing the substrate conveyance device 102 that embodies the above-described technical idea. In other words, the substrate conveyance device 102 that embodies the above-described technical idea has a particularly great technical significance when applied to substrate convey technology employing the “open cassette 450” as a storage container.

### <<Configuration Example of Shutter Mechanism>>

In this section, the shutter and the mechanism for opening and closing the shutter are collectively referred to as the shutter mechanism.

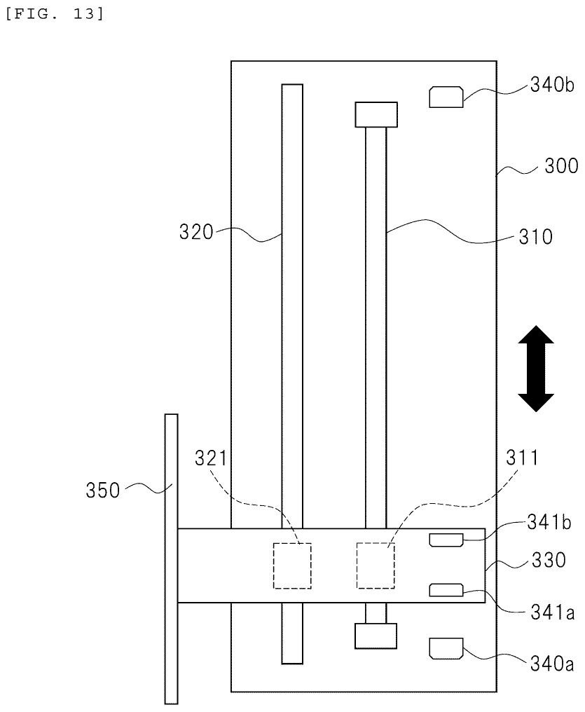

The shutter mechanism may be any mechanism as long as the shutter mechanism can move the shutter in the vertical direction. For example, there is a shutter mechanism that uses an air cylinder and a linear guide. In FIG. 13, the air cylinder is a component that allows a cylinder block 311 to move linearly on a cylinder rod 310 by air pressure. On the other hand, the linear guide is a component that allows a linear guide block 321 to move smoothly on a linear guide rail 320.

As shown in FIG. 6, the air cylinder and the linear guide are attached in parallel to a base 300, and a shutter 350, the air cylinder, and the linear guide are connected by a bracket 330. Here, when air flowing upward is sent to the lower part of the air cylinder, the cylinder block 311 moves linearly to the upper end of the cylinder rod 310, and the linear guide block 321 and shutter 350 connected by the bracket 330 also move linearly to the upper end of the cylinder rod 310.

At this time, the linear guide block 321 smoothens the linear motion of the cylinder block 311, so that the shutter 350 opens smoothly.

On the other hand, when air flowing downward is sent to the upper part of the air cylinder, the cylinder block 311 moves linearly to the lower end of the cylinder rod 310, and the linear guide block 321 and shutter 350 connected by the bracket 330 also move linearly to the lower end of the cylinder rod 310.

At this time, the linear guide block 321 smoothens the linear motion of the cylinder block 311, so that the shutter 350 closes smoothly.

In addition, the other side of the shutter 350 may be provided with a mechanism for linearly moving the shutter 350 similar to the mechanism described above, but when a shutter mechanism on only one side is sufficient to implement linear motion of the shutter 350, the other side of the shutter 350 may simply be provided with a mechanism for guiding the linear motion of the shutter 350.

Furthermore, the shutter mechanism is provided with a function of detecting the opening and closing of the shutter 350, but the detection function may be any function.

For example, a configuration that implements the detection function includes a configuration that uses a non- contact door sensor. The non-contact door sensor is a sensor in which the output of a sensor head turns “ON” when an actuator approaches within a certain distance from the sensor head, and the output of the sensor head turns “OFF” when the actuator moves away from the sensor head by a certain distance.

As shown in FIG. 13, a sensor head 340a and a sensor head 340b are attached to the base 300, while an actuator 341a and an actuator 341b are attached to the bracket 330. Here, the actuator 341a corresponds to the sensor head 340a, and the actuator 341b corresponds to the sensor head 340b. When the shutter 350 is in a closed state, the output of the sensor head 340a is “ON” and the output of the sensor head 340b is “OFF”.

The outputs of the sensor head 340a and the sensor head 340b are input to the control unit 210 (not shown in FIG. 13). When the shutter 350 is opened, the actuator 341a moves away from the sensor head 340a, and as a result, the output of the sensor head 340a becomes “OFF”. On the other hand, the actuator 341b approaches the sensor head 340b, so that the output of the sensor head 340b turns “ON” near the time when the opening of the shutter 350 is completed.

When the output of the sensor head 340b becomes “ON”, the control unit 210 recognizes that the shutter 350 is in an open state. However, when the outputs of both sensor heads 340a and 340b are “ON”, or when the output of the sensor head 340b does not become “ON” within a certain period of time after the shutter 350 starts the opening operation, the control unit 210 is configured to determine that the operation of the shutter 350 is abnormal and display an error message.

When the shutter 350 is closed, the actuator 341b moves away from the sensor head 340b, and as a result, the output of the sensor head 340b becomes “OFF”. On the other hand, the actuator 341a approaches the sensor head 340a, and as a result, the output of the sensor head 340a becomes “ON” near the time when the closing operation of the shutter 350 is completed. When the output of the sensor head 340a becomes “ON”, the control unit 210 recognizes that the shutter 350 is in a closed state. However, when the output of the sensor head 340b is “ON”, or when the output of the sensor head 340a is “OFF” even after a certain amount of time has elapsed since the shutter 350 starts the closing operation, the control unit 210 is configured to determine that the operation of the shutter 350 is abnormal and display an error message.

The shutter mechanism is configured as described above.

### MODIFICATION EXAMPLE 1

Next, the substrate conveyance device 102 in Modification Example 1 will be described.

For example, in FIG. 6, when the operator-side shutter 104 is in a closed state, or when the conveyance robot-side shutter 105 is in a closed state, in case of forcibly opening the operator-side shutter 104 or the conveyance robot-side shutter by a force from outside the device, there is no physical barrier between the operator and the conveyance robot 230.

Therefore, in Modification Example 1, a locking mechanism is provided to forcibly maintain the closed state when the operator-side shutter 104 or the conveyance robot-side shutter 105 is in the closed state. As a result, even when the operator-side shutter 104 or the conveyance robot-side shutter is forcibly opened by a force from outside the device, the closed state can be forcibly maintained by the locking mechanism. Therefore, according to Modification Example 1, it is possible to prevent a situation in which there is no physical barrier between the operator and the conveyance robot 230.

The locking mechanism may be any locking mechanism that can lock the operator-side shutter 104 or the conveyance robot-side shutter 105 in the closed state.

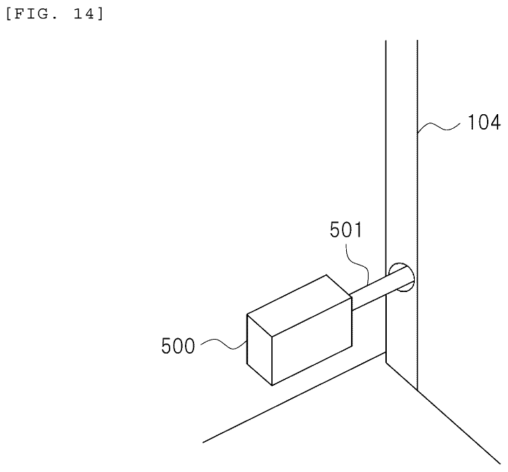

For example, FIG. 14 is a diagram showing an example of the locking mechanism.

FIG. 14 shows a solenoid lock mechanism 500 as an example of the locking mechanism. The solenoid lock mechanism 500 is a mechanism in which a shaft 501 projects when power is supplied, and the shaft 501 retracts when the power supply is cut off. As shown in FIG. 14, the operator-side shutter 104 is provided with a hole into which the shaft 501 can be inserted. In this case, the hole into which the shaft 501 is inserted may be provided in a component attached to the operator-side shutter 104.

For example, when the operator-side shutter 104 is closed, the solenoid lock mechanism 500 is configured to be supplied with power, so that the shaft 501 projects from the solenoid lock mechanism 500 and is inserted into the hole provided in the operator-side shutter 104. This causes the operator-side shutter 104 to be locked.

On the other hand, when the operator-side shutter 104 is opened, the power supply to the solenoid lock mechanism 500 is cut off, so that the shaft 501 is pulled into the solenoid lock mechanism 500, thereby unlocking the operator-side shutter 104.

In this way, according to Modification Example 1, by providing a locking mechanism in the operator-side shutter 104, the operator-side shutter 104 can be forcibly maintained in the closed state. As a result, according to Modification Example 1, it is possible to prevent a situation in which there is no physical barrier between the operator and the conveyance robot 230.

The conveyance robot-side shutter 105 is also provided with a locking mechanism having a similar configuration to the locking mechanism provided in the operator-side shutter 104. Thus, even in the conveyance robot-side shutter 105, the conveyance robot-side shutter 105 can also be forcibly maintained in the closed state. Therefore, by providing locking mechanisms on both the operator-side shutter 104 and the conveyance robot-side shutter 105, it is possible to reliably prevent a situation in which there is no physical barrier between the operator and the conveyance robot 230.

### MODIFICATION EXAMPLE 2

For example, in FIG. 10, the operation of opening the operator-side shutter 401a is performed on the condition that the conveyance robot-side shutter 402a is in a closed state. Similarly, the operation of opening the operator-side shutter 401b is performed on the condition that the conveyance robot-side shutter 402b is in a closed state.

Here, in Modification Example 2, a logic circuit which invalidates a command from the control unit 210 to open based on the output of a sensor that detects the closed state is mounted in the substrate conveyance device 102.

Specifically, in Modification Example 2, in a case where the control unit 210 outputs a control signal to open the operator-side shutter 401a, when the output of the sensor (for example, the sensor head 340b in FIG. 13) that detects the closed state of the conveyance robot-side shutter 402a is “OFF”, the control signal output from the control unit 210 is invalidated by the logic circuit described above.

In this case, in a state where the operator-side shutter 401a and the conveyance robot-side shutter 402a are in the closed state, when the control unit 210 outputs a control signal to open both shutters simultaneously, it may not be possible to prevent both shutters from being opened.

Thus, the output (control signal) from the control unit 210 for opening both the operator-side shutter 401a and the conveyance robot-side shutter 402a is always set to give priority to the control for opening the conveyance robot-side shutter 402a. In other words, when there is an output (control signal) from the control unit 210 that opens both the operator-side shutter 401a and the conveyance robot-side shutter 402a, the output signal) from the control unit 210 for opening the operator-side shutter 401a is invalidated by the logic circuit described above. Thus, even when the conveyance robot 230 extends its arm, for example, it is possible to prevent damage to the conveyance robot 230 due to contact between the conveyance robot 230 and the conveyance robot-side shutter 402a.

### MODIFICATION EXAMPLE 3

In Modification Example 3, for example, in FIG. 6, an example is described in which a safety interlock circuit is implemented in the substrate conveyance device 102 to cut off the driving power supply of the conveyance robot 230 when both the operator-side shutter 104 and the conveyance robot-side shutter 105 are in the open state.

Here, the safety interlock circuit may have any circuit configuration as long as it is capable of cutting off the driving power supply of the conveyance robot 230 in conjunction with both the operator-side shutter 104 and the conveyance robot-side shutter 105 being in the open state.

For example, one example of the safety interlock circuit is a safety interlock circuit that uses a mechanical relay. The mechanical relay is a component in which contacts come into contact when a current is passed through an operation coil, turning the relay contacts “ON”. Here, the driving power supply for the conveyance robot 230 is connected to the relay contact. The input of the operation coil is connected to the output of a sensor that detects the closed state and is provided on each of the operator-side shutter 104 and the conveyance robot-side shutter 105.

Thus, power is supplied to the conveyance robot 230 only while either the operator-side shutter 104 or the conveyance robot-side shutter 105 is in a closed state, and the conveyance robot 230 is configured to be operable. In other words, according to Modification Example 3, when both the operator-side shutter 104 and the conveyance robot-side shutter 105 are in an open state, the power supply to the conveyance robot 230 is cut off.

### MODIFICATION EXAMPLE 4

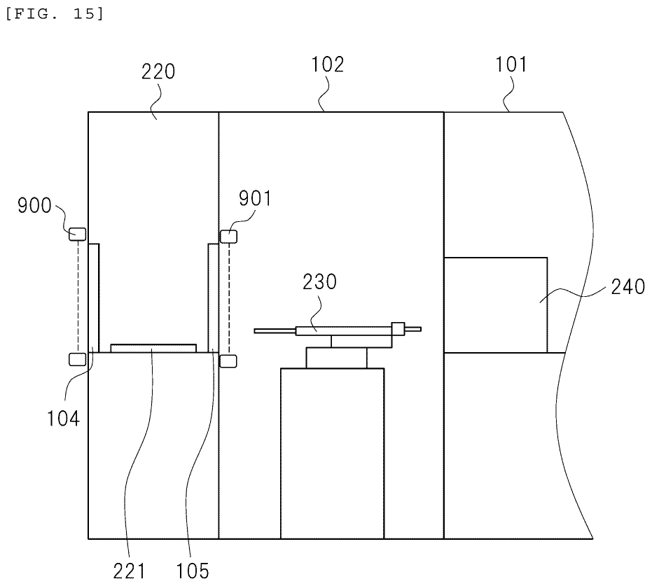

In Modification Example 4, for example, as shown in FIG. 15, an example in which a light curtain 900 is provided to detect that an operator is accessing the storage container mounting portion 220 will be described.

The light curtain 900 is a device configured to detect the access to the storage container mounting portion 220 from the outside of the device including the operator. The substrate conveyance device 102 according to Modification Example 4 is configured not to close the operator-side shutter 104 while the light curtain 900 is detecting the access to the storage container mounting portion 220 from the outside of the device including the operator. Furthermore, the substrate conveyance device 102 according to Modification Example 4 is configured to interrupt the closing operation of the operator-side shutter 104, when the light curtain 900 detects the access to the storage container mounting portion 220 from the outside of the device including the operator, while the operator-side shutter 104 is performing a closing operation.

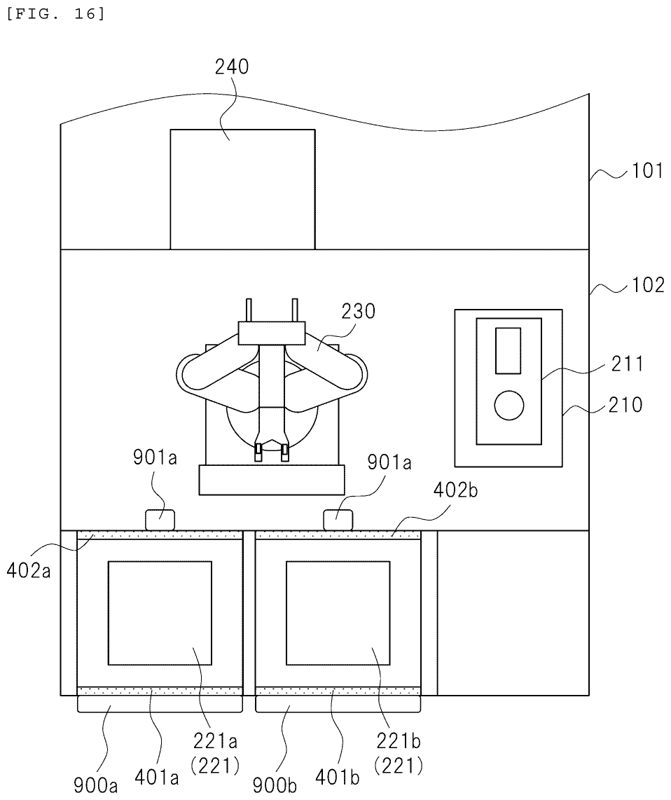

Subsequently, for example, as shown in FIG. 16, when different storage container stands 221a and 221b are provided, a light curtain 900a is provided on the storage container stand 221a, and a light curtain 900b is provided on the storage container stand 221b. Thus, access to the storage container stand 221a can be detected by the light curtain 900a and access to the storage container stand 221b can be detected by the light curtain 900b, so that the closing operations of the operator-side shutter 401a and the operator-side shutter 401b can be restricted based on the detection results by the light curtain 900a and the light curtain 900b. Therefore, according to Modification Example 4, it is possible to prevent the operator from being caught between the operator-side shutter 401a or the operator-side shutter 401b, thereby ensuring the safety of the operator.

Furthermore, for example, even when the light curtain 900a detects access to the storage container stand 221a, when the light curtain 900b does not detect access to the storage container stand 221b, it is possible to continue the closing operation of the operator-side shutter 401b and keep the operator-side shutter 401b in a closed state. In other words, even when the light curtain 900a detects an access during the closing operation of the operator-side shutter 401b, the closing operation of the operator-side shutter 401b continues without being stopped.

In this way, when different storage container stands 221a and 221b are provided, by providing the light curtain 900a for the storage container stand 221a, and the light curtain 900b for the storage container stand 221b, it is possible to prevent unnecessary interruptions to the closing operation while ensuring the safety of the operator.

### MODIFICATION EXAMPLE 5

In Modification Example 5, as shown in FIG. 15, an example in which a light curtain 901 is provided to detect that the conveyance robot 230 is accessing the storage container mounting portion 220 will be described.

The light curtain 901 is a device configured to detect the access to the storage container mounting portion 220 by the conveyance robot 230. Even in Modification Example 5, for example, an example in which the light curtain 901 is provided will be described, but since the route by which the conveyance robot 230 accesses the storage container mounting portion 220 is fixed, a photoelectric sensor or the like may be used instead of the light curtain 901.

The substrate conveyance device 102 according to Modification Example 5 is configured not to close the conveyance robot-side shutter 105 while the light curtain 901 is detecting the access to the storage container mounting portion 220 by the conveyance robot 230. Furthermore, the substrate conveyance device 102 according to Modification Example 5 is configured to interrupt the closing operation of the conveyance robot-side shutter 105, when the light curtain 901 detects the access to the storage container mounting portion 220 by the conveyance robot 230, while the conveyance robot-side shutter 105 is performing a closing operation.

Subsequently, for example, as shown in FIG. 16, when different storage container stands 221a and 221b are provided, a light curtain 901a is provided on the storage container stand 221a, and a light curtain 901b is provided on the storage container stand 221b. Thus, access to the storage container stand 221a can be detected by the light curtain 901a and access to the storage container stand 221b can be detected by the light curtain 901b, so that the closing operations of the conveyance robot-side shutter 402a and the conveyance robot-side shutter 402b can be restricted based on the detection results by the light curtain 901a and the light curtain 901b.

Therefore, according to Modification Example 5, it is possible to prevent the conveyance robot 230 from being caught between the conveyance robot-side shutter 402a or the conveyance robot-side shutter 402b, and thus damage to the conveyance robot 230 can be prevented.

Furthermore, for example, even when the light curtain 901a detects access to the storage container stand 221a, when the light curtain 901b does not detect access to the storage container stand 221b, it is possible to continue the closing operation of the conveyance robot-side shutter 402b and keep the conveyance robot-side shutter 402b in a closed state. In other words, even when the light curtain 901a detects an access during the closing operation of the conveyance robot-side shutter 402b, the closing operation of the conveyance robot-side shutter 402b continues without being stopped.

In this way, when different storage container stands 221a and 221b are provided, by providing the light curtain 901a for the storage container stand 221a, and the light curtain 901b for the storage container stand 221b, it is possible to prevent damage to the conveyance robot 230 while also preventing unnecessary interruptions to the closing operation.

### MODIFICATION EXAMPLE 6

For example, in order to correct the tolerances due to the storage container 200 being a molded product and the clearance errors during conveyance caused by the assembly errors of the substrate conveyance device 102 and the conveyance robot 230, it is necessary to perform an operation called “teaching” in which conveyance parameters of the conveyance robot 230 are set using the substrate conveyance device 102 and the storage container 200 to be used.

“Teaching” is performed by a visual inspection of a service technician, and requires that both the operator-side shutter 104 and the conveyance robot-side shutter 105 be open.

Therefore, the substrate conveyance device 102 in Modification Example 6 is provided with a “teaching mode” that allows the operator to arbitrarily select the open or closed state of the shutter. Furthermore, the substrate conveyance device 102 in Modification Example 6 is provided with an open/close switch for the operator-side shutter 104 and an open/close switch for the conveyance robot-side shutter 105 that can be used only in the “teaching mode”.

When switching from the “operation mode” to the “teaching mode”, the safety interlock circuit described in the above-described Modification Example 3 is disabled, and the operator-side shutter 104 and the conveyance robot-side shutter 105 can be opened simultaneously. On the other hand, monitoring of access to the storage container mounting portion 220 by the light curtain 900 described in the above-described Modification Example 4 and monitoring of access to the storage container mounting portion 220 by the light curtain 901 described in the above-described Modification Example 5 continue in the “teaching mode”.

This prevents the operator from being caught by the operator-side shutter 104 even in the “teaching mode”, ensuring the safety of the operator, and prevents the conveyance robot 230 from being caught by the conveyance robot-side shutter 105, preventing damage to the conveyance robot 230.

The invention made by the inventor has been specifically described above based on the embodiments thereof. However, it goes without saying that the present invention is not limited to the above-described embodiments, and various modifications can be made without departing from the spirit of the invention.

### REFERENCE SIGNS LIST

100: semiconductor inspection device
101: semiconductor substrate processing unit
102: substrate conveyance device
103: shutter
104: operator-side shutter
105: conveyance robot-side shutter
200: storage container
201: semiconductor substrate
210: control unit
211: pre-aligner
220: storage container mounting portion
221: storage container stand
221a: storage container stand
221b: storage container stand
230: conveyance robot
240: upper port
300: base
310: cylinder rod
311: cylinder block
320: linear guide rail
321: linear guide block
330: bracket
340a: sensor head
340b: sensor head
341a: actuator
341b: actuator
350: shutter
400: partition wall
401a: operator-side shutter
401b: operator-side shutter
402a: conveyance robot-side shutter
402b: conveyance robot-side shutter
410: switch
450: open cassette
500: solenoid lock mechanism
501: shaft
900: light curtain
900a: light curtain
900b: light curtain
901: light curtain
901a: light curtain
901b: light curtain

1-13. (canceled)

14. A substrate conveyance device comprising:
a conveyance robot that conveys a substrate;
a first mounting portion in which a first storage container for storing the substrate can be placed;
a first shutter mechanism that is provided to be capable of blocking a first access path when the first storage container or the first mounting portion is accessed from outside the device;
a second shutter mechanism that is provided to be capable of blocking a second access path when the conveyance robot accesses the first storage container;
a first sensor that is provided on the conveyance robot side than the second shutter mechanism, and detects an object on the second access path on the conveyance robot side than the second shutter mechanism; and
a controller that controls opening and closing operations of the first shutter mechanism and the second shutter mechanism, wherein
the controller controls the opening and closing operations of the second shutter mechanism based on a detection result of the first sensor.

15. The substrate conveyance device according to claim 14, further comprising:
a second mounting portion in which a second storage container can be placed;
a third shutter mechanism that is provided to be capable of blocking a third access path when the second storage container or the second mounting portion is accessed from outside the device;
a fourth shutter mechanism provided to be capable of blocking a fourth access path when the conveyance robot accesses the second storage container;
a second sensor that is provided on the conveyance robot side than the fourth shutter mechanism, and detects an object on the fourth access path on the conveyance robot side than the fourth shutter mechanism; and
a partition wall that separates the first mounting portion and the second mounting portion, wherein
the controller controls opening and closing operations of the fourth shutter mechanism based on a detection result of the second sensor.

16. The substrate conveyance device according to claim 14, wherein
in a state in which the first storage container with the substrate stored therein is placed on the first mounting portion,
the controller is configured to perform control to make a transition from a first phase in which the first shutter mechanism is in an open state and the second shutter mechanism is in a closed state to a second phase in which the first shutter mechanism is closed, and then the second shutter mechanism is opened, thereby enabling the conveyance robot to be capable of taking out the substrate from the first storage container.

17. The substrate conveyance device according to claim 16, wherein
in a state in which the first storage container without the substrate stored therein is placed on the first mounting portion,
when the substrate is loaded into the first storage container by the conveyance robot in the second phase, the controller is configured to make a transition from the second phase to a third phase in which the second shutter mechanism is closed and then the first shutter mechanism is opened.

18. The substrate conveyance device according to claim 16, further comprising:
a first switch that triggers the transition from the first phase to the second phase.

19. The substrate conveyance device according to claim 16, wherein
the controller is configured to make a transition from the second phase to a third phase in which the second shutter mechanism is closed and then the first shutter mechanism is opened, and
the substrate conveyance device further comprises a second switch that triggers the transition from the second phase to the third phase.

20. The substrate conveyance device according to claim 15, wherein
the controller is configured to close the third shutter mechanism, and open the fourth shutter mechanism, when the first shutter mechanism is in an open state and the second shutter mechanism is in a closed state.

21. The substrate conveyance device according to claim 15, wherein
the controller is configured to open the third shutter mechanism, and close the fourth shutter mechanism, when the first shutter mechanism is in a closed state and the second shutter mechanism is in an open state.

22. The substrate conveyance device according to claim 14, further comprising:
a first locking mechanism for forcibly maintaining the first shutter mechanism in a closed state when the first shutter mechanism is in a closed state; and
a second locking mechanism for forcibly maintaining the second shutter mechanism in a closed state when the second shutter mechanism is in a closed state.

23. The substrate conveyance device according to claim 14, further comprising:
a third sensor that detects that the first access path is accessed from outside the device, wherein
the controller is configured to stop a closing operation of the first shutter mechanism, when it is detected based on an output from the third sensor that the first access path is being accessed from outside the device during the closing operation of the first shutter mechanism.

24. The substrate conveyance device according to claim 23, wherein
the controller is configured to stop a closing operation of the second shutter mechanism, when it is detected based on an output from the first sensor that the conveyance robot is accessing the second access path during the closing operation of the second shutter mechanism.

25. The substrate conveyance device according to claim 14, wherein
the first storage container is an open cassette.

26. The substrate conveyance device according to claim 14, wherein
the substrate is a semiconductor wafer or a reticle.

27. The substrate conveyance device according to claim 14, wherein
the first sensor is a light curtain or a photoelectric sensor.

28. The substrate conveyance device according to claim 15, further comprising:
a third sensor that detects that the first access path is accessed from outside the device; and a fourth sensor that detects that the third access path is accessed from outside the device.

29. The substrate conveyance device according to claim 28, wherein
the controller is configured to continue the closing operation of the third shutter mechanism without stopping the closing operation, even when it is detected based on an output from the third sensor that the first access path is being accessed from outside the device, if it is not detected based on an output from the fourth sensor that the third access path is being accessed from outside the device.

30. The substrate conveyance device according to claim 28, wherein
the controller is configured to continue the closing operation of the fourth shutter mechanism without stopping the closing operation, even when it is detected based on an output from the first sensor that the second access path is being accessed, if it is not detected based on an output from the second sensor that the fourth access path is being accessed.

31. A substrate conveyance device comprising:
a single conveyance robot that conveys a substrate;
a first mounting portion in which a first storage container for storing the substrate can be placed;
a second mounting portion in which a second storage container for storing the substrate can be placed;
a single operator-side shutter mechanism that is provided to be capable of blocking both access to the first storage container or the first mounting portion from outside the device and access to the second storage container or the second mounting portion from outside the device;
a single conveyance robot-side shutter mechanism that is provided to be capable of blocking both access to the first storage container by the conveyance robot and access to the second storage container by the conveyance robot; and
a controller that controls opening and closing operations of each of the operator-side shutter mechanism and the conveyance robot-side shutter mechanism, wherein
the controller is configured to close the conveyance robot-side shutter mechanism, when the operator-side shutter mechanism is in an open state, and open the conveyance robot-side shutter mechanism, when the operator-side shutter mechanism is in a closed state.
